(19) United States
(12) Patent Application Publication
(10) Pub. No.: US 2012/0281490 A1
(43) Pub. Date: Nov. 8, 2012

(54) SEMICONDUCTOR DEVICE, SEMICONDUCTOR MODULE AND METHOD OF MANUFACTURING THE SAME

(75) Inventor: Young Man CHO, Icheon (KR)

(73) Assignee: Hynix Semiconductor Inc., Icheon (KR)

(21) Appl. No.: 13/291,850

(22) Filed: Nov. 8, 2011

(30) Foreign Application Priority Data
May 2, 2011 (KR) 10-2011-0041590

(51) Int. Cl. G11C 7/06; H01L 29/78; H01L 21/336

(52) U.S. Cl. 365/205; 438/589; 257/330; 257/E29.255; 257/E21.409

(57) ABSTRACT

A technology is capable of improving a process margin in forming a bit line and reducing bit line resistance to improve characteristic of the semiconductor device by forming a cell bit line in a double layer structure are provided. The semiconductor device includes a buried gate buried within a cell region of a semiconductor substrate, a first bit line formed over the semiconductor substrate, a second bit line formed over the first bit line and coupled to the first bit line. The first bit line is formed in the same layer as a peripheral gate of a peripheral circuit region and the second bit line is formed in the same layer as a metal line of the peripheral circuit region.

### CROSS-REFERENCES TO RELATED APPLICATION

The present application claims priority to Korean patent application number 10-2011-0041590 filed on 2 May 2011, which is incorporated by reference in its entirety.

### BACKGROUND OF THE INVENTION

1. Technical Field

The inventive concept relates to a semiconductor device, a semiconductor module and a method of manufacturing the same and, more particularly, to a semiconductor device having a bit line.

2. Related Art

Semiconductor devices include a plurality of unit cells including a capacitor and a transistor. The capacitor is used to store data and the transistor is used to transfer data between the capacitor and a bit line in response to a control signal (a word line) using a semiconductor property in which electric conductivity is changed according to conditions. The transistor has three parts: a gate, a source, and a drain. Charges move between the source and drain according to the control signal input to the gate. The charges move between the source and drain through a channel region using semiconductor properties.

When a conventional transistor is fabricated on a semiconductor substrate, the gate is formed over the semiconductor substrate and then the source and drain are formed by implanting impurities into the semiconductor substrate, thereby forming the channel region between the source and drain below the gate. With the increasing degree of data storage capacity and integration for semiconductor memory devices, there is demand for fabricating unit cells in more scaled down sizes. That is, the design rule of the capacitor and transistor included in the unit cell and thus a channel length of a cell transistor is reduced. Thereby, short channel effect and drain induced barrier lowering (DIBL) in a conventional transistor are caused, and thus reliability is degraded. Phenomena caused due to reduction of the channel length can be overcome when a threshold voltage is maintained so that the cell transistor performs normal operations. Conventionally, as the channel length is shorter, a doping concentration of an impurity in a region in which the channel region is formed in increased.

However, with reduction of the design rule to below 100 nm, increase of the doping concentration in the channel region causes an electric field in a storage node junction to increase, thereby resulting in degradation of refresh characteristic in semiconductor memory devices. To overcome this, a cell transistor having a three-dimensional (3D) channel structure in which a long channel is ensured to maintain a channel length even when the design rule is reduced has been used. That is, although channel width in a horizontal direction is short, the doping concentration can be reduced by the ensured channel length in the horizontal direction and degradation of the refresh characteristic can be prevented.

In addition, as the degree of integration of semiconductor devices is increased, a distance between a gate coupled to a cell transistor and a bit line is reduced. Thereby, parasitic capacitance is increased and an operation margin of a sense amplifier amplifying data transferred through the bit line is degraded, which has a negative effect on the reliability of a semiconductor device. To solve this, a buried gate structure in which a gate is formed within a trench instead of a surface of a semiconductor substrate in order to reduce the parasitic capacitance between a gate and a bit line has been suggested. The buried type gate structure is formed by forming a conductive material within a recess formed in a semiconductor substrate, and forming an insulating layer on the conductive material so that the gate is buried within the semiconductor substrate. Therefore, electrical isolation from a bit line or a bit line contact plug formed over the semiconductor substrate in which a source/drain is formed can be more ensured.

However, in such a buried gate structure, the critical dimension (CD) of a bit line is reduced with the high integration of the device and thus resistance is increased. In addition, it is difficult to improve a net die with reduction in a mat size of a cell.

### SUMMARY

According to one aspect of an exemplary embodiment, a semiconductor device includes a buried gate buried within a cell region of a semiconductor substrate, a first bit line formed over the semiconductor substrate, a second bit line formed over the first bit line and coupled to the first bit line. The first bit line is formed in the same layer as a peripheral gate of a peripheral circuit region and the second bit line is formed in the same layer as a metal line of the peripheral circuit region.

A line width of the second bit line may be larger than the line width of the first bit line. A thickness of the second bit line may be larger than the thickness of the first bit line.

The first bit line and the second bit line may be coupled through a bit line contact plug and the bit line contact plug may be formed in the same layer as a metal contact plug of a peripheral circuit region.

The first bit line and the second bit line may vertically intersect and the bit line contact plug may be disposed at an intersection of the first bit line and a gate.

A thickness of a spacer formed over a sidewall of the second bit line may be larger than the thickness of a spacer formed over a sidewall of the first bit line. The semiconductor device may further include a storage node contact plug disposed in an edge portion of an active region. The semiconductor device may further including a storage node coupled to the storage node contact plug.

According to another aspect of an exemplary embodiment, a semiconductor device includes a semiconductor cell array which includes semiconductor cell, each semiconductor cell including a transistor having a gate and a source/drain region and a storage unit coupled to the transistor, a bit line having a double layer structure and disposed to vertically intersect the gate, a row decoder configured to selects one of word lines of the semiconductor cell array, a column decoder configured to selects one of bit lines of the semiconductor cell arrays, and a sense amplifier configured to senses data stored in a semiconductor cell selected by the row decoder and the column decoder, and an external input/output (I/O) line.

The semiconductor device may further include a data input buffer, a command/address input buffer, and a resistor unit. The semiconductor module may further include an internal command/address bus which transmits a command/address signal to the command/address input buffer.

The external I/O line may be coupled to the semiconductor device.

According to another aspect of an exemplary embodiment, a semiconductor system includes a plurality of semiconductor modules, each semiconductor module including a semiconductor cell array which includes a plurality of semiconductor cell, each semiconductor cell including a transistor having a gate and a source/drain region and a storage unit coupled to the transistor, a bit line having a double layer structure and disposed to vertically intersect the gate, a row decoder which selects one of word lines of the semiconductor cell array, a column decoders which select one of bit lines of the semiconductor cell arrays, and a sense amplifier which senses data stored in a semiconductor cell selected by a row decoder and a column decoder, a command path, and a data path, and a controller which communicates data and command/address with the semiconductor module.

According to another aspect of an exemplary embodiment, a method of manufacturing a semiconductor device includes forming a buried gate buried within a semiconductor substrate, forming a first bit line on the semiconductor substrate of a cell region and a peripheral gate on the semiconductor substrate of a peripheral circuit region, and forming a second bit line on the first bit line of the cell region and coupled to the first bit line and a metal line on the peripheral gate of the peripheral circuit region and coupled to the peripheral gate.

The method may further, after the forming a first bit line, includes a first spacer on a surface of the first bit line.

The method may further, after the forming the first bit line, include first storage node contact plugs at both sides of the first bit line, and before the forming the second bit line, includes forming an interlayer insulating layer on an entire surface of the semiconductor substrate including the first bit line, forming a contact hole exposing the first bit line by etching the interlayer insulating layer, and forming a bit line contact plug by burying a conductive material.

The forming the second bit line may further include forming a bit line conductive material on the bit line contact plug and the interlayer insulating layer, forming a hard mask pattern defining a bit line on the bit line conductive material, and etching the bit line conductive material using the hard mask as an etch mask.

The method may further, after forming the second bit line, include forming a second spacer on a surface of the second bit line.

The forming the second bit line may include forming the second bit line having a larger line width than the first bit line and having a larger line width than the first bit line.

The forming the second spacer may include forming the second spacer having a larger thickness than the first spacer and the method may further, after the forming the second bit line, include second storage node contact plugs coupled to the first storage node contact holes at a both sides of the second bit line.

These and other features, aspects, and embodiments are described below.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a view illustrating a semiconductor cell according to an exemplary embodiment of the present invention, wherein (i) is a plan view and (ii) is a cross-sectional view taken along a line I-I′ of (i);

FIGS. 2A to 2E are views illustrating a method of manufacturing a semiconductor cell according to an exemplary embodiment of the present invention, wherein (i) is a plan view and (ii) is a cross-sectional view taken along a line I-I′ of (i);

FIG. 3 is a view illustrating a memory cell array according to an exemplary embodiment of the present invention;

FIG. 4 is a view illustrating a memory device according to an exemplary embodiment of the present invention;

FIG. 5 is a view illustrating a memory module according to an exemplary embodiment of the present invention; and

FIG. 6 is a view illustrating a memory system according to an exemplary embodiment of the present invention.

### DESCRIPTION OF EXEMPLARY EMBODIMENT

Embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments of the present invention should not be construed as being limited to the particular shapes of regions illustrated herein, but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

Hereinafter, an exemplary embodiment of the present invention will be described in detail with reference to accompanying drawings.

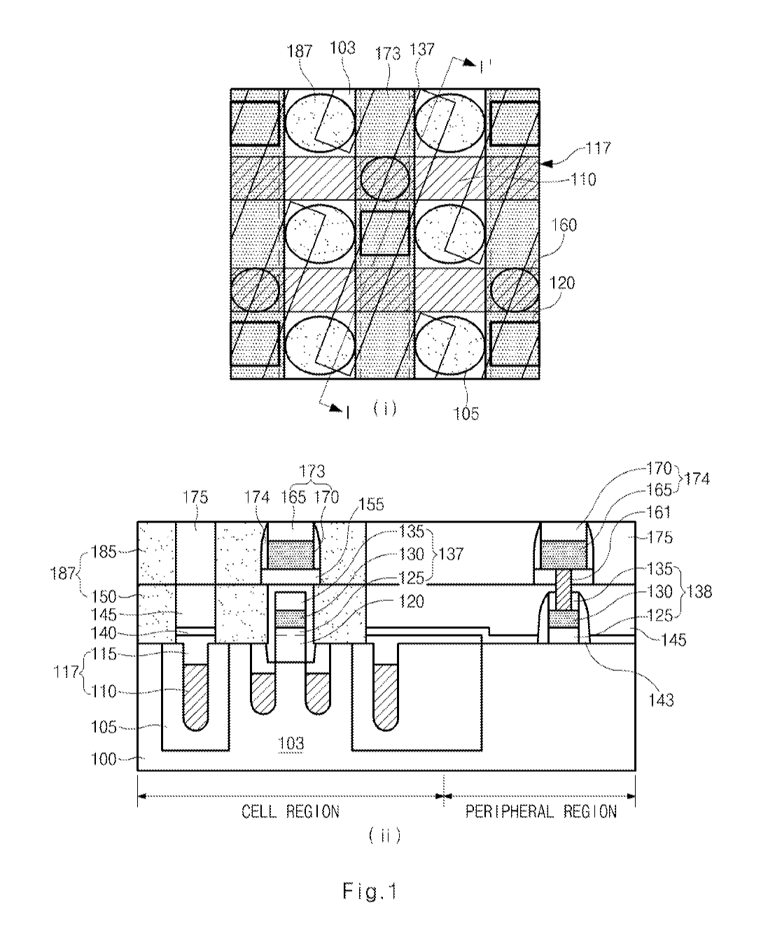

FIG. 1 is a view illustrating a semiconductor cell including a bit line according to an exemplary embodiment of the inventive concept, wherein (i) is a plan view of a cell region and (ii) is a cross-sectional view of the cell region and a peripheral circuit region of the semiconductor device taken along a line I-I′ of (i).

Referring to FIG. 1, the semiconductor cell includes a gate 117, a bit line vertically intersecting the gate 117, and a storage unit. The configuration elements of the semiconductor cell will be described in more detail.

First, buried gate 117 is formed within a semiconductor substrate 100 in which a device isolation layer 105 defining an active region 103 is formed. The buried gate 117 is formed as a line type, and two buried gates 117 intersect one active region 103. A first bit line contact plug 120 is formed over the active region 103 between buried gates 117. The first bit line 137 is formed to be coupled to the first bit line contact plug 120. The first bit line 137 is formed as a line type to vertically intersect the buried gate 117. At this time, the first bit line 137 may be formed over the same layer as a peripheral gate 138 of a peripheral circuit region. The first bit line 137 may be formed to have a smaller linewidth and a lower height than a bit line formed in the related art.

A second bit line contact plug 160 is formed over the first bit line 137. The second bit line contact plug 160 is formed over the same layer as a metal contact plug 161 of a peripheral circuit region. Further, a second bit line 173 is formed to be coupled to the first bit line 137 through the second bit line contact plug 160. The second bit line 173 is formed over the same layer as a metal line 174 of a peripheral circuit region. The second bit line 173 is formed to have a larger linewidth than the first bit line 137. The second bit line 173 is formed to have a higher surface level than the first bit line 137. Here, the second bit line contact plug 160 may be disposed at any position of an overlapping portion of the first bit line 137 and the second bit line 173. Preferably, the second bit line contact plug 160 is disposed on a portion in which the buried gate 117 intersects the first bit line 137 as shown in FIG. 1(i). Because FIG. 1(ii) is a cross-sectional view taken along a line I-I′ of FIG. 1(i), the second bit line contact plug 160 disposed at the intersection of the buried gate 117 and the first bit line 137 is not shown in FIG. 1(ii).

Storage node contact plugs 187 are formed at both edge portions of the active region 103. The second bit line plug 160 is disposed at the intersection of the buried gate 117 and the first bit line 137 and thus a distance between the storage node contact plug 187 and the second bit line contact plug 160 is increased as compared to the related art. Therefore, self align contact (SAC) fail can be prevented. A storage node is coupled to the storage node contact plug 187.

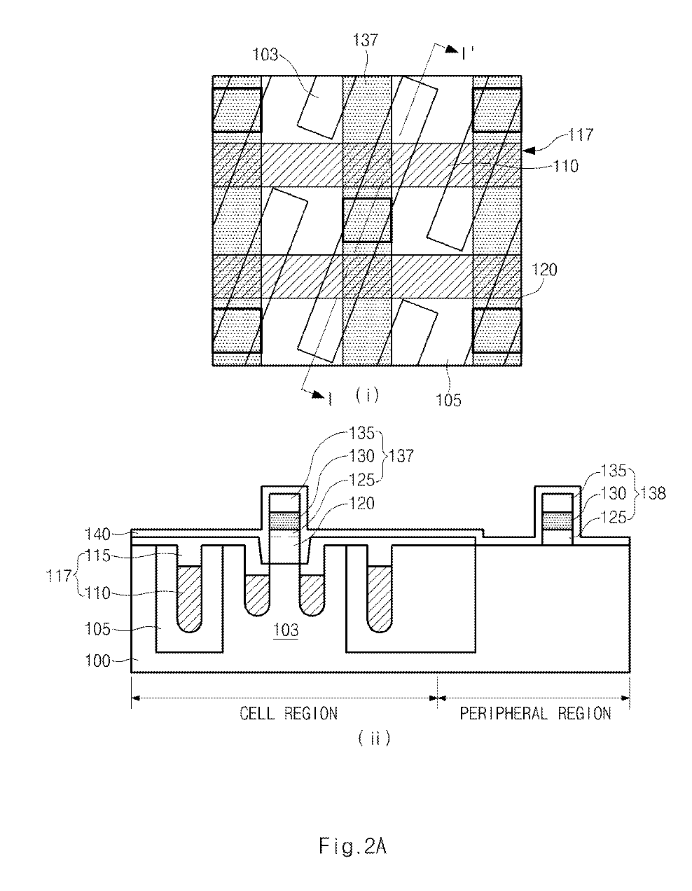

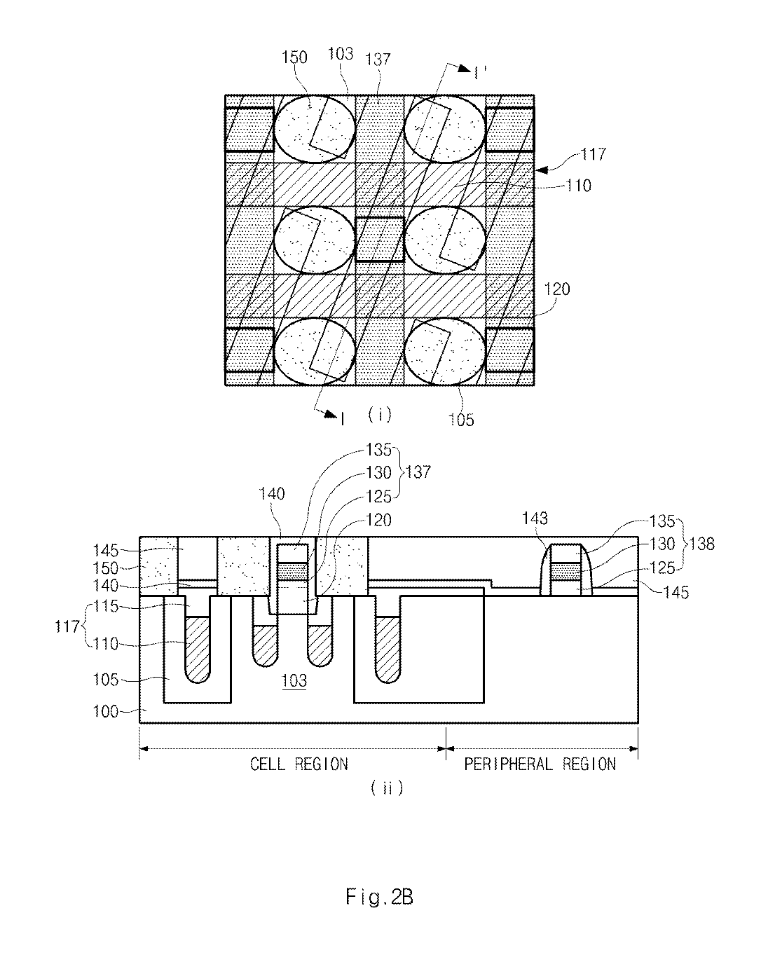

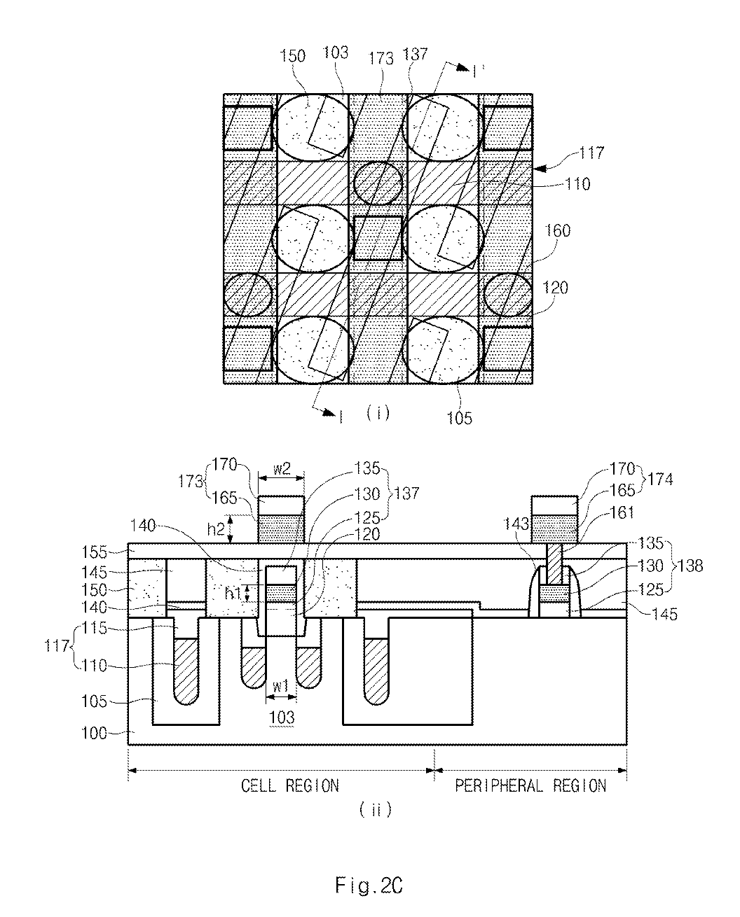

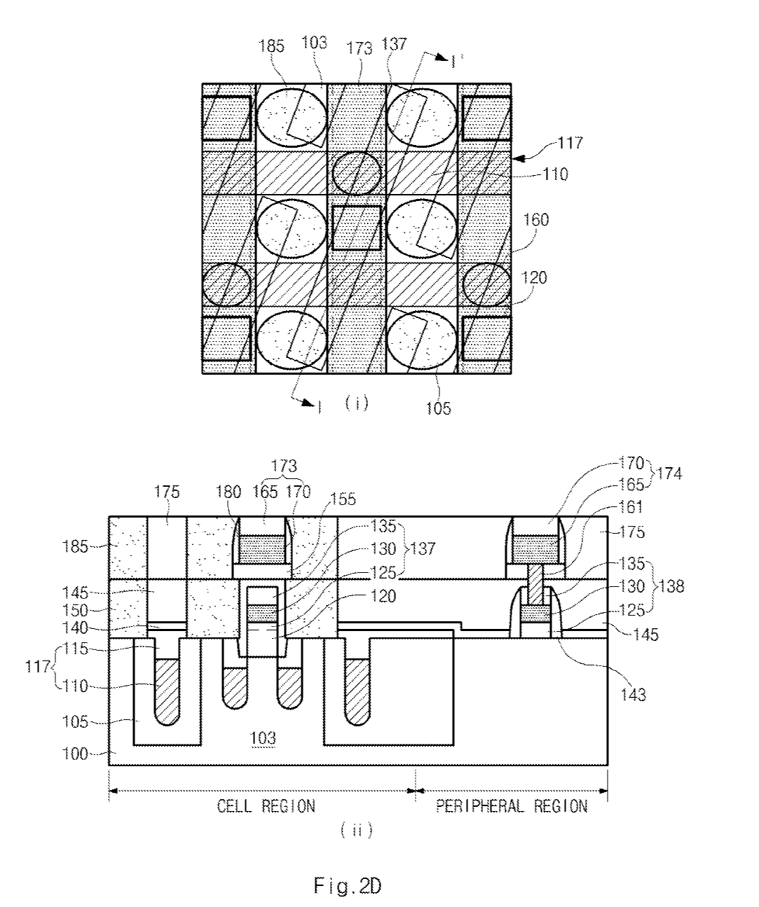

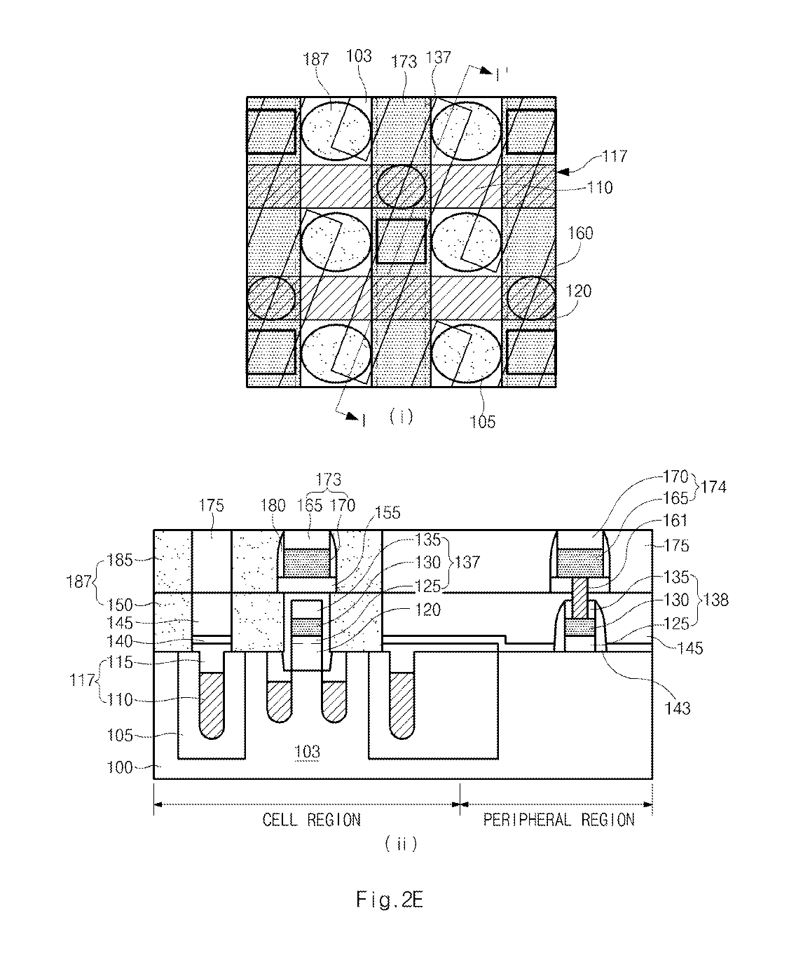

Hereinafter, a method of manufacturing a semiconductor device having the above-described structure according to an exemplary embodiment of the present invention will be described. FIGS. 2A to 2E are views illustrating a method of manufacturing a semiconductor device according to an exemplary embodiment, wherein (i) is a plan view of a cell region and (ii) is a cross-sectional view of the cell region and a peripheral circuit region taken along a line I-I′ of (i).

Referring to FIG. 2A, a semiconductor substrate 100 is etched to form a trench for device isolation. An oxide layer is buried within the trench for device isolation and an etching process for planarization is performed to form a device isolation layer 105 defining an active region 103. Subsequently, the device isolation layer 105 and the active region 103 are etched to form recesses. Because active region 103 formed of a silicon material has different selectivity than device isolation layer 105 formed of an oxide material, the depths of the recesses will differ accordingly. In the peripheral circuit region, since a conventional planar gate protruding from a surface of the semiconductor substrate 100 is formed when a bit line is formed in the following process, recesses are preferably not formed.

A gate oxidation process is performed to form a gate oxide layer (not shown) within the recesses. Next, a barrier metal layer (not shown) is formed over the surfaces of the recesses on which a gate oxide layer (not shown) is formed. Here, the barrier metal layer (not shown) may be formed of a titanium nitride (TiN) layer and may have a thickness of 50 Å to 70 Å. A conductive material 110 is formed at lower portions of the recesses in which the barrier metal layer (not shown) is formed. Here, the conductive material 110 may be formed of a tungsten (W) layer, a TiN layer, or a combination thereof. Preferably, the conductive material 110 may be formed of a W layer. The W layer may be formed by a chemical vapor deposition (CVD) method. A sealing nitride layer 115 is deposited on the semiconductor substrate 100 including the recesses within which the conductive material 110 is buried to form the buried gates 117. The buried gates 117 are formed to intersect one active region 103. Here, the sealing nitride layer 115 may be formed so that the conductive material 110 for the buried gate 117 is entirely buried.

Next, a mask pattern (not shown) defining a bit line contact region is formed over the sealing nitride layer 115. Here, the mask pattern (not shown) may be formed of carbon, silicon oxynitride (SiON), or a combination thereof. The sealing nitride layer 115 is etched as the mask pattern using a barrier to form a bit line contact hole (not shown) and then the mask pattern is removed. Here, a bit line contact hole (not shown) is formed to expose a portion of the semiconductor substrate 100 between the buried gates 117 formed in the active region 103. At this time, the sealing layer 115 of the buried gate 117 formed over the active region 103 is partially exposed.

Next, a polysilicon layer, a bit line conductive layer 130 and a hard mask layer are formed over the entire surface of the semiconductor substrate 100 including the bit line contact hole (not shown). Here, the bit line conductive layer 130 may include tungsten (W), tungsten nitride (WN), tungsten silicide (WSi), or a combination thereof. The bit line conductive layer 130 may be deposited using a CVD method. The hard mask is formed of a material including a nitride layer.

Afterward, the hard mask layer is etched to become hard mask pattern 135 defining a bit line and a bit line contact plug. The polysilicon layer and the bit line conductive layer 130 are etched using the hard mask pattern as an etch mask to form a first bit line contact plug 120 and a first bit line 137 including a polysilicon layer 125, a bit line conductive layer 130 and a hard mask pattern 135. The first bit line contact plug 120 is simultaneously formed over an inner surface of the bit line contact hole. In addition, the first bit line 137 may be formed to vertically intersect the buried gate 117. The first bit line 137 may be formed to have a lower height than a bit line of the related art.

At this time, a peripheral gate 138 is simultaneously formed in the peripheral circuit region when the first bit line 137 is formed in the cell region so that the peripheral gate 138 has the same stacking structure as the first bit line 137. As the height of the first bit line 137 is lowered, the height of the peripheral gate 138 simultaneously formed together with the first bit line 137 is also lowered. As the height of the peripheral gate 138 is lowered, a process margin of a tilt angle is increased in an ion implant process for forming a lightly doped drain (LDD) region and a source/drain region in the peripheral circuit region.

Next, a spacer layer 140 is formed over surfaces of the sealing nitride layer 115, the first bit line contact plug 120 and the first bit line 137. The spacer layer 140 may be formed of a material including a nitride layer.

Referring to FIG. 2B, a mask pattern (not shown) opening the peripheral circuit region is formed over the semiconductor substrate 100 including the first bit line 137 in which the spacer layer 140 is formed and then the spacer layer 140 is exposed in the peripheral circuit region. Subsequently, spacers 143 are formed at both sides of the gate 138.

A first interlayer insulating layer 145 is formed over the entire surface of the semiconductor substrate 100 including the first bit line 137 over which the spacer layer 140 is formed. A mask pattern (not shown) defining a storage node contact region is formed over the first interlayer insulating layer 145. The interlayer insulating layer 145, the spacer layer 140 and the sealing nitride layer 115 are etched using the mask pattern (not shown) as an etch mask to form first storage node contact holes exposing the semiconductor substrate 100. The first storage node contact holes may be formed at edge portions of the active region 103 at both sides of the first bit line 137.

Next, a conductive material is formed within the first storage node contact holes and a planarization process is performed until reaching portions of the first interlayer insulating layer 145, thereby forming first storage node contact plugs 150. The first storage node contact plugs 150 may be formed of a material including a polysilicon layer.

Referring to FIG. 2C, a second interlayer insulating layer 155 is formed over the first interlayer insulating layer 145 and the first storage node contact plugs 150. The second interlayer insulating layer 155, the spacer layer 140 and the hard mask layer 135 are etched to form a contact hole exposing the metal layer 130 of the first bit line. At the same time, a contact hole exposing the metal layer 130 of the peripheral gate 138 is formed in the peripheral circuit region.

Afterward, a conductive material is formed within the contact holes of the cell region and the peripheral area to form a second bit line contact plug 160 and a metal contact plug 161. The second bit line contact plug 160 may be disposed in any position of a connection portion of the first bit line 137 and a second bit line 173 formed in the following process. Preferably, as shown in FIG. 2C(i), the second bit line 173 is disposed at an intersection of the buried gate 117 and the first bit line 137. Since FIG. 2C(ii) is a cross-sectional view taken along a line I-I′ of FIG. 2C(i), the second bit line contact plug 160 disposed at the intersection of the buried gate 117 and the first bit line 137 is not shown in FIG. 2C(ii).

Next, a bit line conductive layer 165 is formed over the second interlayer insulating layer 155 including the second bit line contact plug 160 and a hard mask pattern 170 defining a bit line is formed over the bit line conductive layer 165. The bit line conductive layer 165 may include a W layer and be formed using a physical vapor deposition (PVD) method. Subsequently, the bit line conductive layer 165 is etched using the hard mask pattern 170 as an etch mask to form the second bit line 173 coupled to the second bit line contact plug 160. Simultaneously, a metal line 174 is formed to be coupled to the metal contact plug 161 in the peripheral circuit region. At this time, the second bit line 173 may be formed to have a larger line width (w2) than the first bit line 137 (W1) and have a higher height (h2) than the first bit line 137 (h1). Thus, since the second bit line 173 is formed to have a larger size than the first bit line 137, the second bit line 173 can reinforce the first bit line 137 which is formed to have a smaller size than a bit line of the related art. Further, as the second bit line 173 is formed to have a larger size, sufficient space between the bit line and the storage node contact plug formed at both side of the bit line to prevent SAC can be ensured.

Referring to FIG. 2D, a spacer layer is formed over the second interlayer insulating layer 155 including the second bit line 173 and an etching back process is performed to form a spacer 180 on a sidewall of the second bit line 173. Spacer 180 may be formed to have a larger line width than the spacer layer 140 formed over the sidewall of the first bit line 137. When the spacer 180 formed over the sidewall of the second bit line 173 is formed to have a thicker thickness, parasitic capacitance can be reduced.

The third interlayer insulating layer 175 is formed over the entire surface of the semiconductor substrate including the second bit line 173 of which the spacer 180 is formed over the sidewall. The third interlayer insulating layer 175 is etched to form a second storage node contact hole exposing the first storage node contact plug 150. Next, a conductive material is buried within the second storage node contact hole and a planarization process is performed until the second bit line 173 is exposed, thereby forming the second storage node contact plug 185. At this time, as shown in FIG. 2D(i), since the second bit line contact plug 160 is formed to be spaced apart from the storage node contact plug 187, SAC fail can be suppressed.

Referring to FIG. 2E, a storage node (not shown) is formed over the second storage node contact plug 185 to be coupled to the second storage node contact plug 185. The storage node (not shown) may be formed in a cylinder type, but the inventive concept is not limited thereto and the storage node (not shown) may be formed in a concave type or pillar type.

As described above, since the bit line is formed as a double layer structure, bit line resistance can be reduced and thus the size of the cell array is increased and number of dies can be increased.

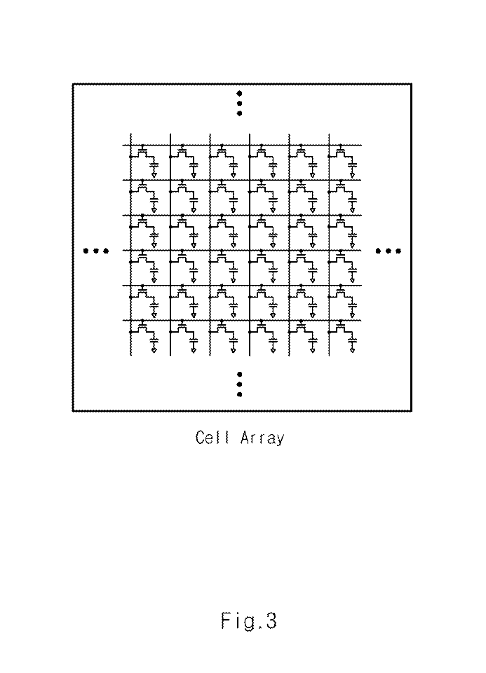

FIG. 3 is a circuit diagram illustrating a memory cell array including the above-described exemplary embodiments of the present invention.

Typically, the memory cell array includes a plurality of memory cells and each memory cells includes one transistor and one capacitor. Such memory cells are disposed at intersections of bit lines BL1, . . . , BLn and word lines WL1, . . . , WLm. The memory cells store and output data based on voltages applied to the bit lines BL1, . . . , BLn and the word lines WL1, . . . , WLm selected by the column decoder and row decoder.

As shown in FIG. 3, in the memory cell array, the bit lines BL1, . . . , BLn are formed to extend in a first direction (or “bit line direction”) as a length direction and the word lines WL1, . . . , WLm are formed to extend in a second direction (or “word line direction”) as a length direction so that the bit lines BL1, . . . , BLn and the word lines WL1, . . . , WLm are disposed to intersect each other. A first terminal (for example, a drain terminal) of the transistor is coupled to the bit line BL1, . . . , BLn, a second terminal (for example, a source terminal) is coupled to the capacitor, and a third terminal (for example, a gate terminal) may be a word line WL1, . . . , WLm.

Here, the bit line is formed as illustrated in FIG. 1 and has a stacking structure of the first bit line and the second bit line.

As described above, the memory cell array according to the exemplary embodiment can reduce parasitic capacitance between the bit lines, and thus improve characteristics of the devices.

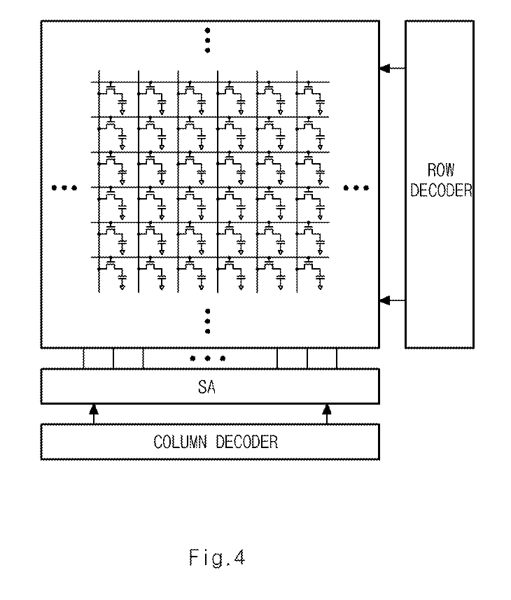

FIG. 4 is a block diagram illustrating a memory device according to an exemplary embodiment of the present invention.

Referring to FIG. 4, the memory device may include a memory cell array, a row decoder, a column decoder, and a sense amplifier. The row decoder selects a word line corresponding to a memory cell in which a read or write operation is to be performed and outputs a word line select signal (RS) to the memory cell array. The column decoder selects a bit line corresponding to a memory cell in which a read or write operation is to be performed and outputs a bit line select signal (CS) to the memory cell array. Further, the sense amplifier senses data stored in a memory cell selected by the row decoder and a column decoder.

Here, the bit line is formed as shown in FIG. 1 and may have a stacking structure of the first bit line and second bit line. As described above, a memory device according to the exemplary embodiment can reduce bit line resistance and prevent SAC failure, and thus improve characteristics of a memory device.

A memory device according to an embodiment of the present invention may be applied to dynamic random access memories (DRAMs), but it is not limited thereto and it may be applied to static random access memories (SRAMs), flash memories, ferroelectric random access memories (FeRAMs), magnetic random access memories (MRAMs), or phase change random access memories (PRAMs).

A memory device according to an embodiment of the present invention can be used, for example, in desktop computers, portable computers, computing memories used in servers, graphics memories having various specs, and mobile electronic devices as technology continues to evolve. Further, the above-described semiconductor device may be provided to various digital applications such as mobile recording mediums including a memory stick, multimedia card (MMC), secure digital (SD), compact flash (CF), extreme digital (xD) picture card, and a universal serial bus (USB) flash device as well as various applications such as MP3P, portable multimedia player (PMP), a digital camera, a camcorder, and a mobile phone. A semiconductor device may be applied to a technology such as multi-chip package (MCP), disk on chip (DOC), or embedded device. The semiconductor device may be applied to a CMOS image sensor to be provided to various fields such as a camera phone, a web camera, and a small-size image capture device for medicine.

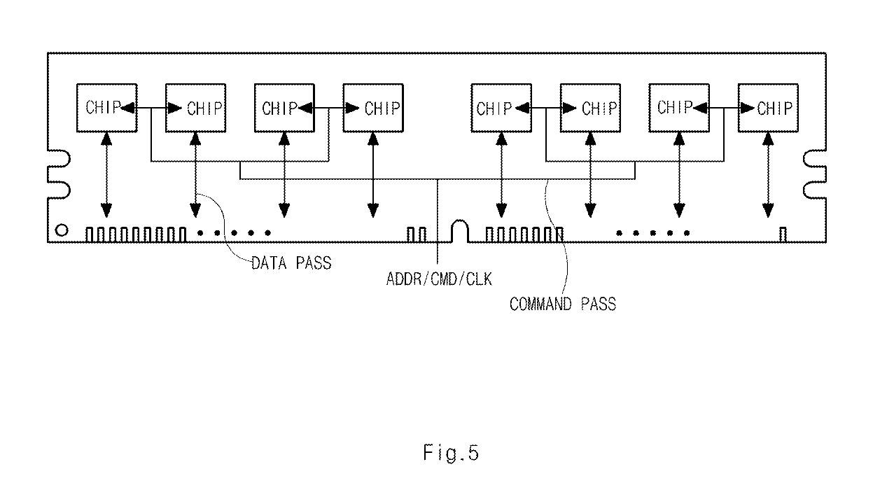

FIG. 5 is a diagram illustrating a memory module according to an exemplary embodiment of the present invention.

Referring to FIG. 5, the memory module includes semiconductor devices mounted on a module substrate, a command path which allows the semiconductor devices to receive control signals (address signal (ADDR), command signals (CMD), clock signals (CLK)) from an external controller (not shown), and a data path which is coupled to the semiconductor devices and transfers data to the semiconductor devices.

The command path and data path used by embodiments of the present invention can be the same or similar to those used in a conventional semiconductor module.

Although FIG. 5 illustrates 8 semiconductor devices mounted on a front of the semiconductor module, additional semiconductor devices are also mounted on a rear of the module substrate in the same manner. That is, the semiconductor devices may be mounted on one side or both sides of the module substrate and the number of semiconductor devices is not limited to eight on either side. In addition, the material and construction of the module substrate are not specifically limited in a fashion particular to the present invention.

The bit line of such a memory module is formed as shown in FIG. 1 and may have a stacking structure of the first bit line and second bit line.

As described above, a memory module according to an embodiment of the present invention can reduce bit line resistance and prevent SAC failure, and thus, improve characteristics of a device.

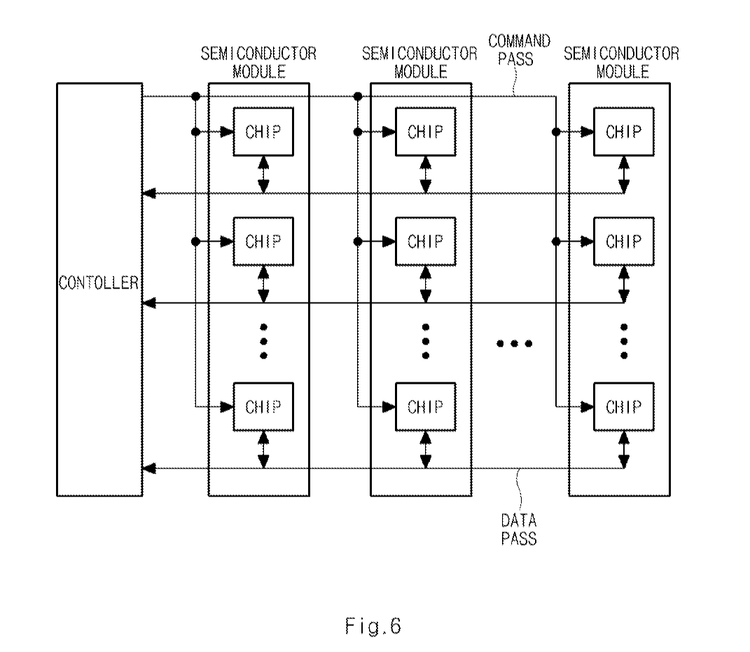

FIG. 6 is a diagram illustrating a memory system according to an embodiment of the present invention.

Referring to FIG. 6, a memory system includes a semiconductor module including one or more memory devices. The memory system includes a memory controller that communicates data and command/address signals through the memory module and a system bus.

A bit line formed of such a memory system is formed as shown in FIG. 1 and may have a stacking structure of the first bit line and second bit line.

As described above, the memory system according to an embodiment can reduce bit line resistance and prevent SAC failure, and thus improve characteristics of the devices. More specifically, the semiconductor memory device according to an embodiment of the present invention provides the following effects.

First, the cell bit line is formed in a double layer structure and thus resistance of the cell bit line can be reduced.

Secondly, with reduction of the resistance of the cell bit line, the size of the cell array can be increased and thus net die can be increased.

Thirdly, the cell bit line is formed in a double layer structure and thus the height of the bit line formed below can be reduced. Thereby, a process margin can be increased and a process margin in tilted ion implantation for forming the source/drain of the peripheral gate can be improved.

Fourthly, the distance between the contact plug of the cell bit line and the storage node contact plug is increased and thus SAC fail can be prevented.

Fifthly, the spaces are thickly formed over the sidewall of the upper cell bit line to reduce parasitic capacitance of the cell bit line and increase the sensing margin.

The above embodiment of the present invention is illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

What is claimed is:

1. A semiconductor device, comprising:
a buried gate buried within a cell region of a semiconductor substrate;
a first bit line formed over the semiconductor substrate; and
a second bit line formed over the first bit line and coupled to the first bit line,
wherein the first bit line is formed in the same layer as a peripheral gate of a peripheral circuit region and the second bit line is formed in the same layer as a metal line of the peripheral circuit region.

2. The semiconductor device of claim 1, wherein the line width of the second bit line is larger than the line width of the first bit line.

3. The semiconductor device of claim 1, wherein the thickness of the second bit line is larger than the thickness of the first bit line.

4. The semiconductor device of claim 1, wherein the first bit line and the second bit line are coupled through a bit line contact plug.

5. The semiconductor device of claim 4, wherein the bit line contact plug is formed in the same layer as a metal contact plug of a peripheral circuit region.

6. The semiconductor device of claim 5, wherein first bit line and the second bit line vertically intersect each other.

7. The semiconductor device of claim 6, wherein the bit line contact plug is disposed at an intersection of the first bit line and a gate.

8. The semiconductor device of claim 1, wherein a thickness of a spacer formed over a sidewall of the second bit line is larger than a thickness of a spacer formed over a sidewall of the first bit line.

9. The semiconductor device of claim 1, further comprising a storage node contact plug disposed in an edge portion of an active region.

10. The method of claim 9, further comprising a storage node coupled to the storage node contact plug.

11. A semiconductor module, comprising:
a semiconductor cell array which includes a plurality of semiconductor cells, each semiconductor cell including a transistor having a gate and a source/drain region and a storage unit coupled to the transistor;
a bit line having a double layer structure and disposed to vertically intersect the gate;
a row decoder configured to select one of word lines of the semiconductor cell array;
a column decoder configured to select a bit line of the semiconductor cell array;
a sense amplifier configured to sense data stored in a semiconductor cell selected by the row decoder and the column decoder; and
an external input/output (I/O) line.

12. The semiconductor module of claim 11, wherein the semiconductor device further includes a data input buffer, and a command/address input buffer.

13. The semiconductor module of claim 12, further comprising:
an internal command/address bus which transmits a command/address signal to the command/address input buffer; and
a resistor unit.

14. The semiconductor module of claim 11, wherein the external I/O line is electrically coupled to the semiconductor device.

15. A semiconductor device, comprising:
a plurality of semiconductor modules, each semiconductor module including a semiconductor cell array which includes a plurality of semiconductor cells, each semiconductor cell including a transistor having a gate and a source/drain region and a storage unit coupled to the transistor, a bit line having a double layer structure and disposed to vertically intersect the gate, a row decoder configured to select one of word lines of the semiconductor cell array, a column decoder configured to select one of bit lines of the semiconductor cell arrays, and a sense amplifier configured to sense data stored in a semiconductor cell selected by a row decoder and a column decoder;
a command path;
a data path; and
a controller configured to transmit data or a command/address signal to or from the semiconductor module.

16. A method of manufacturing a semiconductor device, comprising:
forming a buried gate buried within a semiconductor substrate;
forming a first bit line over the semiconductor substrate of a cell region and a peripheral gate over the semiconductor substrate of a peripheral circuit region; and
forming a second bit line over the first bit line of the cell region and coupled to the first bit line and a metal line over the peripheral gate of the peripheral circuit region and coupled to the peripheral gate.
